(19) United States
(12) Patent Application Publication
(10) Pub. No.: US 2016/0276499 A1
(43) Pub. Date: Sep. 22, 2016

(54) SOLAR CELL

(71) Applicant: SOLARWORLD INNOVATIONS GMBH, Freiberg (DE)

(72) Inventors: Phillipp RICHTER, Freiberg (DE); Roman SCHIEPE, Dresden (DE); Stefan STECKEMETZ, Freiberg (DE)

(73) Assignee: SOLARWORLD INNOVATIONS GMBH, Freiberg (DE)

(21) Appl. No.: 15/018,907

(22) Filed: Feb. 9, 2016

(30) Foreign Application Priority Data
Mar. 17, 2015 (DE) 202015101360.4

(51) Int. Cl. H01L 31/02; H01L 31/0216

(52) U.S. Cl. CPC H01L 31/02008; H01L 31/02167

(57) ABSTRACT

Solar cell including a semiconductor substrate with a first and second side, a first contact structure disposed in the region of the first side of the semiconductor substrate and contacting the semiconductor substrate, a passivation layer with openings disposed on the second side of the semiconductor substrate, and a second contact structure disposed on the passivation layer, which locally contacts the semiconductor substrate through the openings of the passivation layer, wherein the first contact structure has a strip-shaped connection element and contact fingers connected to the connection element, and wherein the passivation layer has an openings-free region extending along the connection element in a region under the strip-shaped connection element of the first contact structure.

### BACKGROUND

The present invention relates to a solar cell, comprising a semiconductor substrate with a first and second side, a first contact structure disposed in the region of the first side of the semiconductor substrate and contacting the semiconductor substrate, a passivation layer with openings disposed on the second side of the semiconductor substrate, and a second contact structure disposed on the passivation layer, which locally contacts the semiconductor substrate through the openings of the passivation layer.

Solar cells are employed for the purpose of converting the electromagnetic radiation energy, particularly sunlight into electric energy. The energy conversion is based on that radiation in a solar cell is subjected to an absorption, whereby positive and negative charge carriers (Electron-hole pairs) are generated. The free charge carriers generated are further separated from each other to be forwarded to the separated contacts.

Conventional solar cells have a semiconductor substrate, in which two regions with different conductivity or doping are configured. There is a p-n junction between both the regions, which are also referred to as base and emitter. The presence of an inner electric field is associated therewith, which causes the separation of the charge carriers generated by radiation.

For tapping the charge carriers, the solar cells have metallic contact structures on the front and rear side of the semiconductor substrate. Usually, strip-shaped connection elements and contact fingers are located on the front side and flat connection elements and a metallic layer surrounding the connection elements on the rear-side. The front and rear side connection elements are used for connecting the cell connectors.

In a construction referred to as PERC solar cell (Passivated Emitter and Rear Cell), the semiconductor substrate has a passivation layer with openings on the rear-side. The contact structure associated therewith is disposed on the passivation layer and locally contacts the semiconductor substrate through the openings of the passivation layer.

### SUMMARY

The object of the present invention consists of claiming a solution for an improved solar cell.

This object is accomplished by the features of the independent claims. Further advantageous embodiments of the invention are claimed in the dependent claims.

According to an aspect of the invention, a solar cell is proposed. The solar cell has a semiconductor substrate with a first and second side, a first contact structure disposed in the region of the first side of the semiconductor substrate and contacting the semiconductor substrate, a passivation layer with openings disposed on the second side of the semiconductor substrate, and a second contact structure disposed on the passivation layer. The second contact structure locally contacts the semiconductor substrate through the openings of the passivation layer. The first contact structure has a strip-shaped connection element and contact finger connected to the connection element. The passivation layer has an openings-free region extending along the connection element in a region below the strip-shaped connection element of the first contact structure.

The solar cell is based on the fact that the region under the strip-shaped connection element of the first contact structure can be shadowed. Consequently, during the operation of the solar cell, none or substantially no charge carriers can be generated in this region by the radiation absorption and none or substantially no power can be generated at this position. Accordingly, the passivation layer under the connection element of the first contact structure has an openings-free region extending along the connection element, i.e. a region without openings. The openings-free regions can be strip-shaped or rectangular similar to the connection element.

In this configuration, the region under the connection element of the first contact structure is not used for contacting the semiconductor substrate and not for transmission of electricity through the second contact structure. Because of this, an efficient passivation of the semiconductor substrate through the passivation layer is possible. By means of the passivation layer, inter alia, a recombination of charge carriers on the surface of the substrate and yield losses associated therewith can be suppressed. Since in the region under the connection element of the first contact structure, none or substantially no charge carriers are generated, the closed configuration of the passivation layer in this region also causes none or just a minor or negligible increase in the series resistance.

In the following, further possible details and embodiments of the solar cell are described in more details.

The strip-shaped connection element of the first contact structure, which can also be referred to as Busbar, can be used for connecting a cell connector. Such a cell connector can be configured in the form of a strip-shaped conductor, for example in the form of a tin-plated copper strip, and connected to the connection element by soldering. Therefore, the connection element or the first contact structure can be configured from a solderable metallic material, for example Silver. The connection of the cell connector can be made within the scope of manufacturing a photovoltaic module. The solar cell can be electrically connected to another solar cell or a cross-connector of the photovoltaic module via the cell connector. The above mentioned shadowing in the region under the connection element can be caused by the connection element and the cell connector connected to the connection element.

The second contact structure can cover the entire passivation layer. The second contact structure can be locally connected to the semiconductor substrate through the openings of the passivation layer. The second contact structure can have a connection structure for connecting a (different) cell connector, which can be configured similarly from a solderable metallic material such as Silver. The connection structure can be disposed in the region under the strip-shaped connection element of the first contact structure. Further, the second contact structure has a metallic layer of another or different metallic material, for example Aluminium, surrounding the connecting structure. Possible details for this are explained in more details further below.

The first side of the semiconductor substrate can be a front side, and the second side of the semiconductor substrate can be a rear side. The front side of the semiconductor substrate and thereby the corresponding solar cell front sides can be facing the light radiation (sunlight) during the operation of the solar cell.

In this context, the solar cell can further have an antireflective layer on the first side of the semiconductor substrate in order to support the launching of a light radiation into the semiconductor substrate. In this way, the first contact structure can or at least the contact fingers can extend through the antireflective layer to the semiconductor substrate and contact the substrate.

Moreover, the solar cell can be a so-called PERC-solar cell (Passivated Emitter and Rear Cell).

The semiconductor substrate can be a Silicon substrate. The semiconductor substrate can have a base-emitter structure or a p-n junction, whereby a separation of the charge carriers generated in the substrate by radiation absorption can be caused during the operation of the solar cell.

In another embodiment, the openings of the passivation layer can be disposed in an engraving of parallel extending lines, so that the second contact structure locally contacts the semiconductor substrate in linear contacting regions. This configuration makes possible the simple manufacture of the solar cell. The openings of the passivation layer can be introduced, for example, by means of a Laser in the passivation layer configured beforehand on the entire surface on the semiconductor substrate. Further, the arrangement of the openings of the passivation layer in an engraving enables a homogeneous local contacting of the semiconductor substrate through the second contact structure.

The openings and thereby, the linear contacting regions are omitted in the openings-free region of the passivation layer.

It is possible that linear contacting regions are disposed on both sides of the openings-free region or border this on both sides.

In another embodiment, the openings of the passivation layer are configured in the form of continuous linear structures and/or in the form of line segments. With this, a homogeneous local contacting of the semiconductor substrate through the second contact structure can be supported.

The openings-free region of the passivation layer extending along the connection element of the first contact structure can have a width in the range of one millimetre or a width in the lower millimetre-range in single digit. For example, a width in the range of one millimetre to three millimetres is possible.

The size or width of the openings-free region of the passivation layer can be adapted to the width of the strip-shaped connection element of the first contact structure. Here, an overlapping region can be considered, in which the passivation layer is covered by the strip-shaped connection element of the first contact structure. According to another embodiment, for this purpose, it is provided that the openings of the passivation layer are disposed spaced from the overlapping region of the connection element. This embodiment, in which the openings-free region has a larger width than the overlapping region of the connection element, supports a reliable passivation of the semiconductor substrate through the passivation layer.

In a configuration of the solar cell with linear contacting regions, linear contacting regions are correspondingly disposed at a distance from the overlapping region of the connection element.

In another embodiment, the openings of the passivation layer are partially disposed within the overlapping region of the connection element. Here, the openings-free region has a smaller width than the overlapping region. This embodiment is based on the possible fact that in the overlapping region of the connection element, there no complete shadow is present at least on the border and thereby, charge carrier can be generated at this position during the operation of the solar cell. These charge carriers can be tapped via the openings of the passivation layer partially available within the overlapping region and thereby, the second contact structure locally contacting the semiconductor substrate at this position.

In a configuration of the solar cell with linear contacting regions, accordingly, linear contacting regions can be partially disposed within the overlapping region of the connection element.

Further, a configuration can be considered, in which openings of the passivation layer or linear contacting regions reach the overlapping region of the connection element. Here, the overlapping region and the openings-free region can be mutually congruent.

In another embodiment, the second contact structure has a connection structure with several connection segments and a metallic layer laterally surrounding the connection segments of the connecting structure. The connection structure with the connection segments can be disposed in the region under the strip-shaped connection element of the first contact structure. The connection structure has a first metallic material, which is solderable. The metallic layer has a second metallic material. The metallic layer locally contacts the semiconductor substrate only through the openings of the passivation layer.

The above mentioned embodiment, in which the metallic layer only locally contacts the semiconductor substrate and thereby the passivation layer under the connection structure or under the connection segments is not opened, enables a lower contact resistance. The segmented construction of the connection structure further offers the possibility to realize the connection structure with a lower proportion of the first metallic material, and thereby to achieve a cost saving. The cost advantage can be perceptible, for example, when the first metallic material is Silver. The second metallic material can be a cheap material such as Aluminum.

If the solar cell has linear contacting regions or the openings of the passivation layer are disposed in an engraving of parallel extending lines, the connection segments of the connection structure can be disposed between the lines of the engraving.

The segmented connection structure of the second contact structure can be used for connecting a cell connector by means of soldering. In the soldering process, a device can be used, which has several peaks or solder pins for pressing the cell connector to the connection structure. Here, the segmented configuration of the connection structure can likewise prove as advantageous. It may be considered to configure the connection structure such that the connection segments and the solder pins are mutually coordinated with respect to their position, so that the connection segments can be located in the soldering process respectively at the corresponding positions under the solder pins. This enables to connect the cell connectors to the connection structure, reliably and with a high solder joint strength.

In another embodiment, the segmented connection structure has connection segments separated from each other. With this, a material saving and thereby cheap configuration of the connection structure can be supported.

In another embodiment, the segmented connection structure has interconnected connection segments. Here, two or respectively two connection segments of the connection structure can be interconnected by a similar connection bridge having the first metallic material. In the region or under such a connection bridge, as also under the connection segments, the passivation layer can be unopened. The connected configuration of connection segments of the connection structure offers the possibility of connecting a cell connector to the connection structure even between the connection segments.

Notwithstanding the above mentioned configurations, the solar cell can also be configured such that the connection structure of the second contact structure used for connecting a cell connector and surrounded by the metallic layer is realized not as segmented structure, but in the form of a flat connection element.

According to another aspect of the invention, an arrangement of a solar cell and a cell connector is proposed. The solar cell has the above described construction or a construction corresponding to one or more of the above described embodiments. The cell connector is connected to the strip-shaped connection element of the first contact structure.

The abovementioned arrangement can be part of a photovoltaic module. Through the cell connector, the solar cell can be electrically connected to another solar cell or a cross-connector of the module. Based on the strip-shaped connection element of the first contact structure or of the cell connector connected thereto, the region under the connection element can be shadowed, so that none or substantially no charge carriers are generated at this position during operation of the solar cell. The passivation layer of the solar cell has an openings-free region in the shadowed region adjusted accordingly, whereby an efficient passivation of the semiconductor substrate can be achieved.

For determining the size or width of the openings-free region of the passivation layer, an overlapping region can be considered, in which the passivation layer is covered by the cell connector. According to an embodiment, it is provided in this respect that the openings of the passivation layer are disposed spaced from the overlapping region of the cell connector. This embodiment, in which the openings-free region has a larger width than the overlapping region of the cell connector, supports a reliable passivation of the semiconductor substrate through the passivation layer.

In a configuration of the solar cell with linear contacting regions, accordingly, linear contacting regions are disposed at a distance from the overlapping region of the cell connector.

In another embodiment, the openings of the passivation layer are disposed partially within the overlapping region of the cell connector. Here, the openings-free region has a smaller width than the overlapping region. This embodiment is based on the possible fact that in the overlapping region of the cell connector, no shadow is present at least at the border, and therefore charge carriers can be generated at this position during the operation of the solar cell. These charge carriers charge can be tapped partially through the openings of the passivation layer present within the overlapping region and thereby, the second contact structure locally contacting the semiconductor substrate at this position. In a configuration of the solar cell with linear contacting regions, accordingly, linear contacting regions can be disposed partially within the overlapping region of the cell connector.

In addition, a configuration is possible, in which openings of the passivation layer or linear contacting regions reach the overlapping region of the cell connector. Here, the overlapping region and the openings-free region can be mutually congruent.

The cell connector and thereby der overlapping region of the cell connector can have, for example, a width in the range of one to two millimetres.

Further embodiments can be considered for the solar cell and the arrangement of solar cell and cell connector. For example, another cell connector can be connected to the second contact structure or to the connection structure thereof. Further, the solar cell can be configured such that several cell connectors can be respectively connected to the first and second contact structure.

For this purpose, the first contact structures can have several strip-shaped connection elements. The several connection elements can be configured extending parallel to each other, and are connected to contact fingers.

Accordingly, the passivation layer of the solar cell has several openings-free regions under the several connection elements of the first contact structure adapted thereto. Each openings-free region can be located under a corresponding connection element and extend along the same.

With reference to the second contact structure, a configuration with several, if necessary, connection structures configured segmented and a metallic layer surrounding the connection structures can be considered. Here, the solar cell can have, for example, a row of adjacently disposed connection structures, to which a single cell connector can be connected. The solar cell can be configured with several parallel rows of connection structures for connecting several cell connectors.

In such configurations of the solar cell, the features and details of an openings-free region and a connection element or a connection structure mentioned above can be used accordingly.

The above mentioned features and/or the advantageous configurations and improvements of the invention given in the subordinate claims—except for example in cases of clear dependencies or inconsistent alternatives—can be used individually or but also in any combination with each other.

The invention is explained in more details in the following with the help of the schematic figures. They show:

### BRIEF DESCRIPTION OF DRAWINGS

FIG. 1 shows a top view representation of a front side of a solar cell with a front side contact structure, which has connection elements and contact fingers;

FIG. 2 shows a top view representation of a rear side of the solar cell with a rear side contact structure, which has connection structures and a metallic layer;

FIG. 3 shows a top view representation of a rear side passivation layer of the solar cell with openings, which are disposed in an engraving, so that linear contacting regions are present, wherein the passivation layer has adapted openings-free regions on the connection elements of the front side contact structure;

FIG. 4 shows a side sectional view of the solar cell;

FIGS. 5 and 6 show configurations of openings of the passivation layer of the solar cell;

FIG. 7 shows a top view representation of linear contacting regions, which are disposed, spaced from an overlapping region;

FIG. 8 shows a top view representation of linear contacting regions, which are disposed partially within an overlapping region;

FIG. 9 shows a top view representation of a cell connector connected to a connection element of the front side contact structure;

FIG. 10 shows a top view representation of linear contacting regions, which are disposed partially within an overlapping region, including a representation of a segmented connection structure with separated connection segments disposed on the rear side of the solar cell;

FIG. 11 shows a side sectional view of the solar cell in the region of the segmented connection structure;

FIG. 12 shows a top view representation of linear contacting regions, which are disposed spaced from an overlapping region, including a representation of a segmented connection structure disposed on the rear side of the solar cell;

FIG. 13 shows a top view representation of linear contacting regions, which are disposed partially within the overlapping region, including a representation of a segmented connection structure with connected connection segments disposed on the rear side of the solar cell; and

FIG. 14 shows a top view representation of linear contacting regions, which are disposed, spaced from an overlapping region, including a representation of a connection element disposed on the rear side of the solar cell.

### DETAILED DESCRIPTION OF EMBODIMENTS

The possible configurations of a solar cell 100 are described based on the following schematic figures. The solar cell 100 is characterized by a reliable rear side passivation. It is pointed out that the figures are only of schematic nature and are not to scale. In this sense, the components and structures shown in the figures are represented enlarged or reduced for better understanding, and if necessary, in a number differing from an actual number. In the same manner, it is possible that the solar cell 100 has further components and structures in addition to those shown and described.

The figures include top view representations, in which a two-dimensional coordinate system is indicated (c.f. FIG. 1) based on direction arrows indicated with x, y and oriented right angular. This is used partially for describing the geometrical factors.

FIG. 1 shows a top view representation of a front side of a solar cell 100. The front side is facing the light radiation (Sunlight) during the operation of the solar cell 100. The solar cell 100 has a metallic contact structure 130 on the front side. According to the configuration shown here, the contact structure 130 includes several or four strip-shaped connection elements 131 and a plurality of contact fingers 135, which are connected to the connection elements 131. The connection elements 131, which can also be referred to as Busbars, extend mutually parallel along the y-direction. The contact fingers 135 extend perpendicular to these along the x-direction.

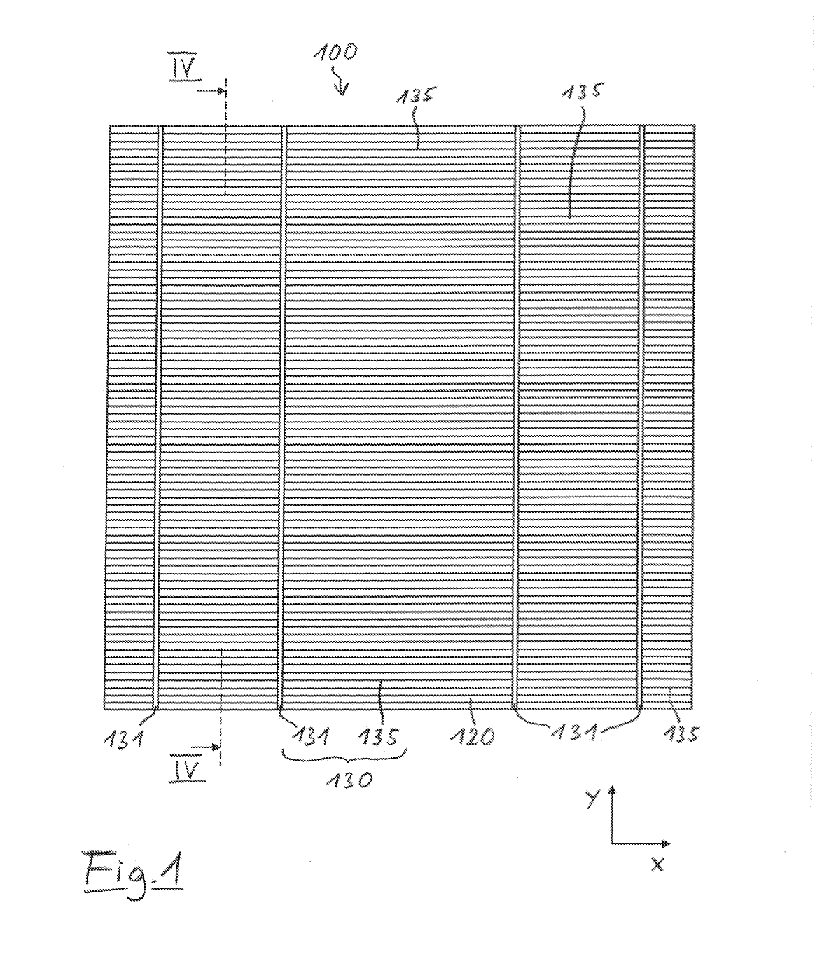

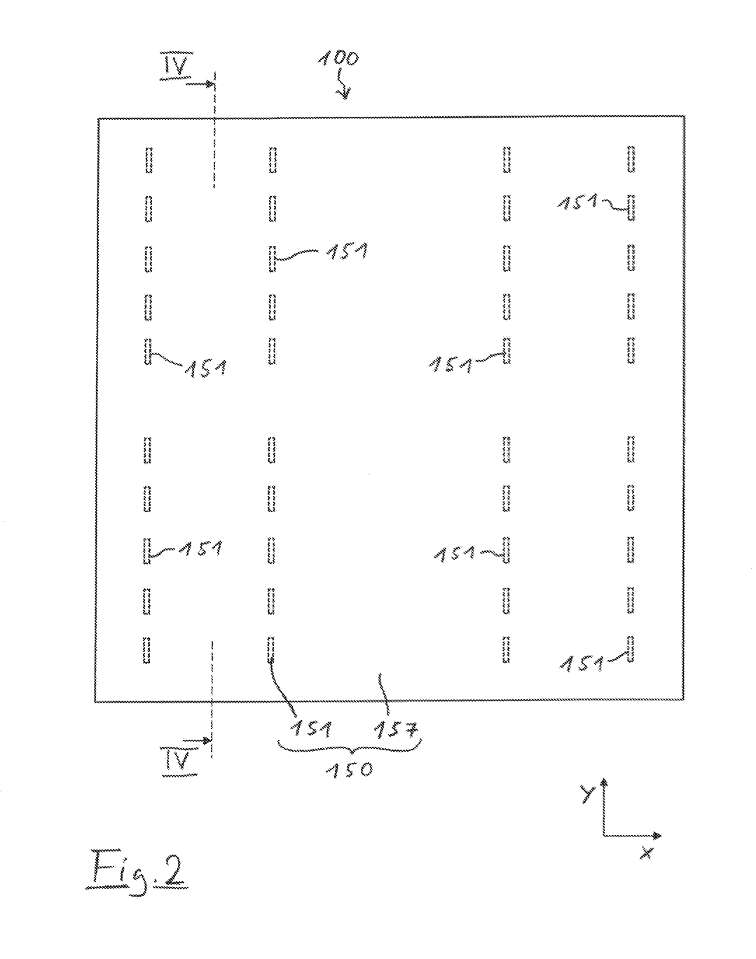

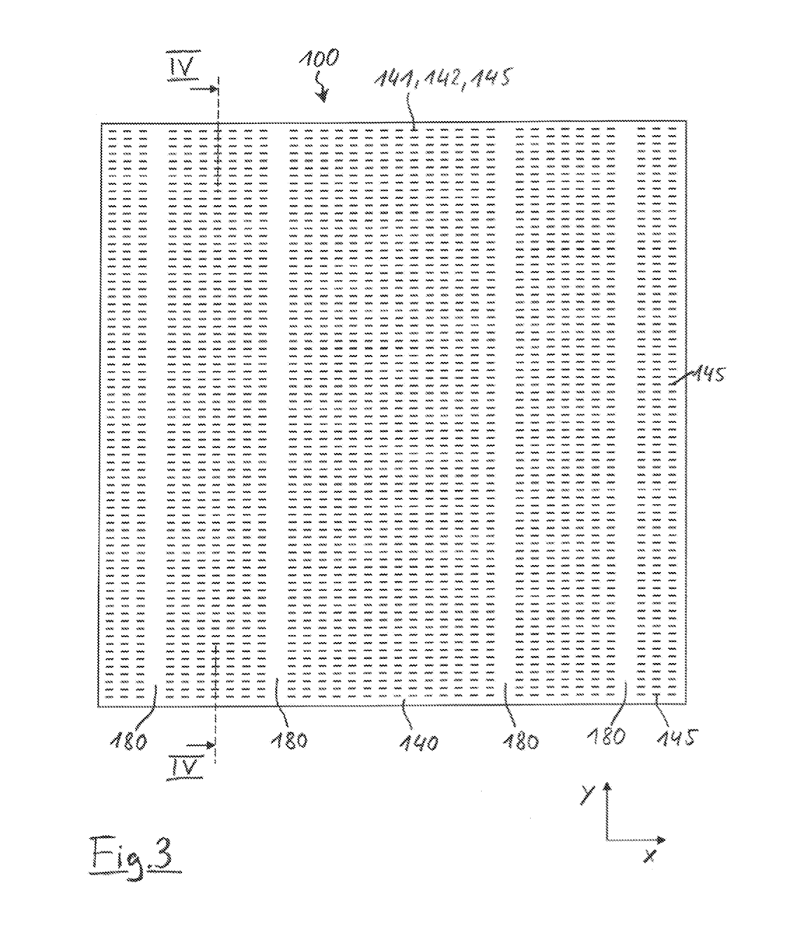

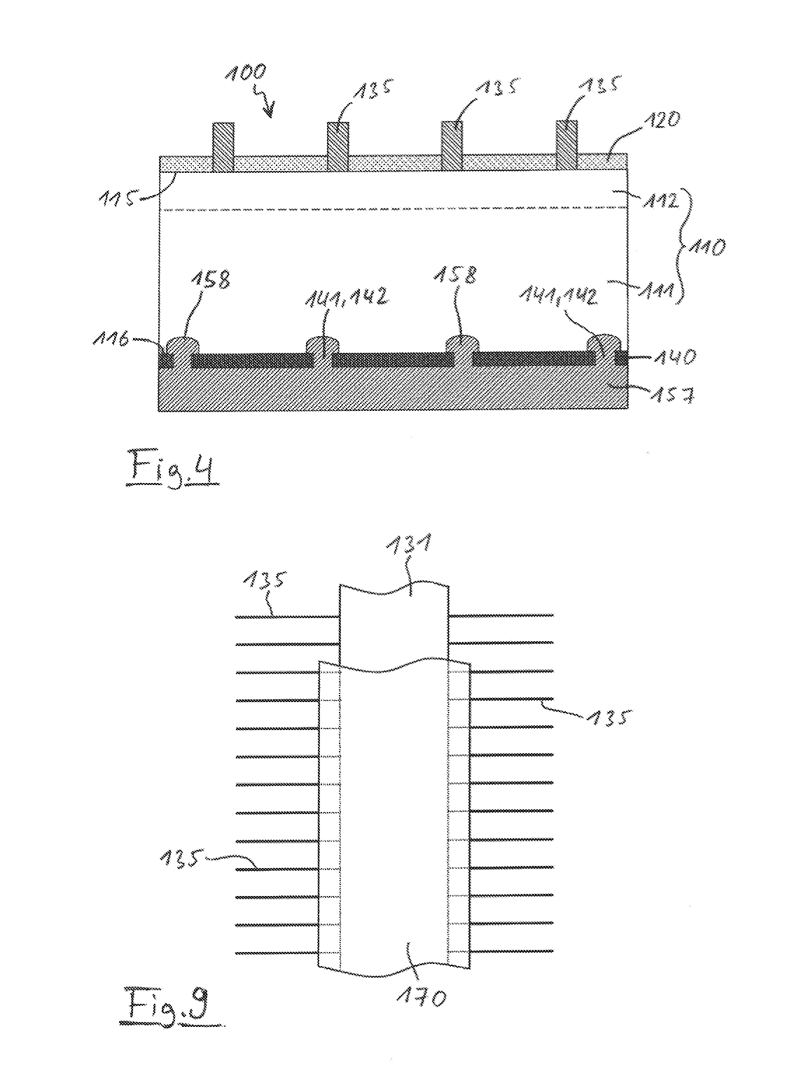

Further details to the front side contact structure 130 and the remaining construction of the solar cell 100 become clear with the help of the side sectional view from FIG. 4. The sectional plane of FIG. 4 relates to the section lines indicated in FIG. 1 and in the further FIGS. 2, 3.

As shown in FIG. 4, the solar cell 100 has a semiconductor substrate 110 with two opposed sides, i.e. a front side 115 and a rear side 116. The front side contact structure 130 is configured for contacting the semiconductor substrate 110 at the front side 115. For this purpose, at least the contact fingers 135 are connected to the semiconductor substrate 110.

It is represented in FIG. 4 that the solar cell 100 additionally has a dielectric antireflective layer 120 on the front side 115 of the semiconductor substrate 110. The contact fingers 135 extend through the antireflective layer 120 to the front side 115 of the semiconductor substrate 110, so that the contact fingers 135 can contact the semiconductor substrate 110.

The connection elements 131 of the front side contact structure 130 shown in FIG. 1 can likewise extend through the antireflective layer 120 to the substrate 110 and thereby contact through the substrate 110. In an alternative configuration, the connection elements 131 are exclusively located on the antireflective layer 120, and the semiconductor substrate 110 is contacted (each not represented) only through the contact fingers 135.

The front side contact structure 130 can be produced, while a metallic paste is pressed on the semiconductor substrate 110 provided with the antireflective layer 120. In a high temperature process referred to as firing, the paste can be solidified and electrically connected to the substrate 110. In this process, a thorough etching of the antireflective layer 120 can be caused by corrosive additives in the paste, whereby the contact structure 130 is connected to the substrate 110 through the antireflective layer 120. If it is provided only for the contact fingers 135, a paste with corrosive additives can be printed for the contact fingers 135 and another paste without corrosive additives for the connection elements 131.

The semiconductor substrate 110 of the solar cell 100 could be a Silicon substrate or a Silicon wafer. As shown in FIG. 4, the semiconductor substrate 110 has two regions 111, 112 with different doping and therefore a p-n junction. This is related to the presence of an inner electric field, which is used for insulating the charge carriers generated in the substrate 110 by radiation absorption during the operation of the solar cell 100. The differently doped regions are referred to as base 111 and emitter 112. For example, the base 111 can be p-doped, and the emitter 112 configured on the front side and contacted through the contact structure 130 or the contact fingers 135 thereof, can be n-doped.

The connection elements 131 of the front side contact structure 130 shown in FIG. 1 are used for connecting the cell connectors (c.f. FIG. 9 with the cell connector 170). On the four connection elements 131, four and likewise extending along the y-direction cell connectors 170 can be connected. In this way, the solar cell 100 in a photovoltaic module can be electrically connected with another solar cell or even a cross-connector of the module (not represented). For this purpose, the front side contact structure 130 is configured from a solderable metallic material such as Silver. In this way, the cell connector can be connected to the connection elements 131 by means of soldering. For example, tin-plated copper strips can be used as cell connectors.

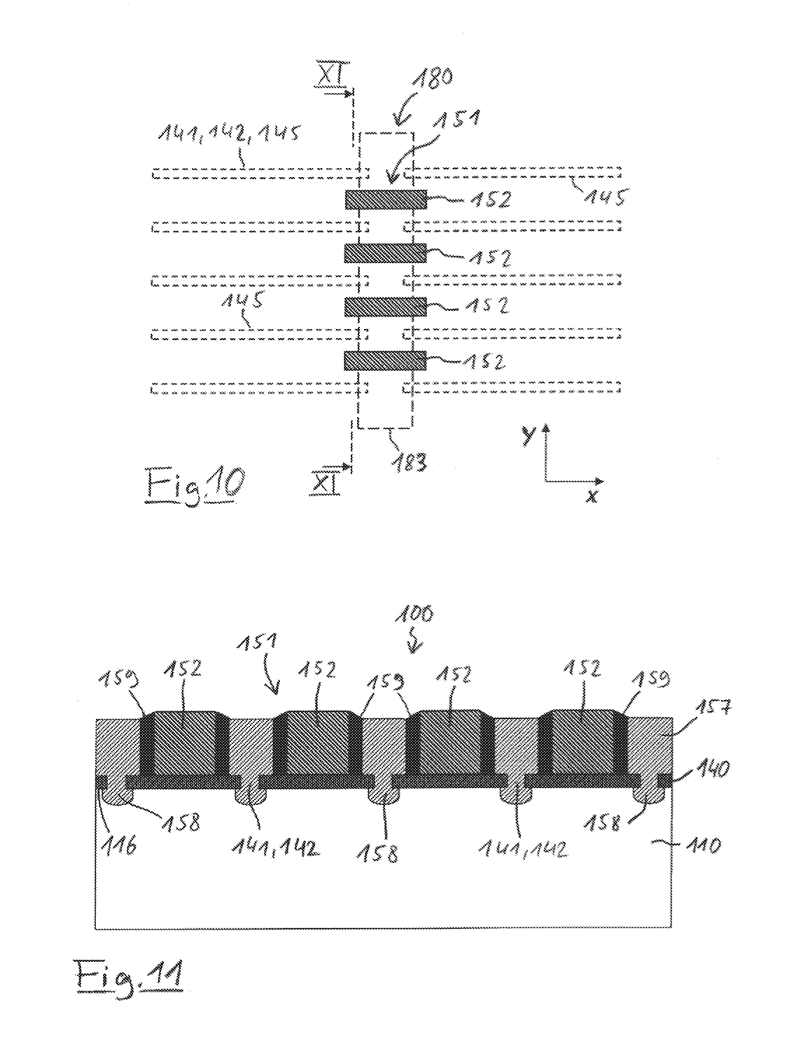

The solar cell 100 has another metallic contact structure 150 for rear side contacting of the semiconductor substrate 110 or the base 111 thereof. In this context, FIG. 2 shows a top view representation of a rear side of the solar cell 100 opposite the front side. The rear side contact structure 150 illustrated here has several connection structures 151 and a metallic layer 157 laterally surrounding the connection structures 151. The connection structures 151 can be configured segmented, as will be explained in more details further below (for example, c.f. FIG. 10).

The connection structures 151 of the rear side contact structure 150 serve as the front side connection elements 131 for connecting the cell connectors, to make an electrical connection to another solar cell or a cross-connector (not represented) in a photovoltaic module. For this purpose, the connection structures 151 likewise configured from a solderable metallic material or from Silver. The metallic layer 157 is configured from a different or cheap metallic material such as Aluminum.

As shown in FIG. 2, the solar cell 100 has several—parallel and extending along y-direction—rows of respectively several or ten adjacently disposed connection structures 151. A cell connector extending along y-direction can be connected (not represented) to each of the rows of connection structures 151. According to the configuration shown here, the solar cell 100 has four rows of connection structures 151 corresponding to the four front side connection elements 131, whereby as required, four cell connectors can be connected thereto. The connection structures 151 are matched with regard to the position on the front side connection elements 131 and disposed such that the rows of connection structures 151 are respectively located in regions under the connection elements 131.

It is also represented in FIG. 4 that the solar cell 100 has a passivation layer 140 on the rear side 116 of the semiconductor substrate 110. It is possible to reduce a recombination of charge carriers on the surface of the semiconductor substrate 110 by means of the passivation layer 140. The passivation layer 140 can be configured monolayer from a dielectric material. A multilayer configuration of the passivation layer 140 is also possible, in which the passivation layer 140 has a stack of layers made of different dielectric materials (not represented).

As represented in FIG. 4, the passivation layer 140 has a plurality of openings 141, 142. During the manufacture of the solar cell 100, the openings 141, 142 can be introduced in the passivation layer 140 on the semiconductor substrate 110, previously configured completely by means of a Laser. The rear side contact structure 150 is located on the passivation layer 140 and locally contacts the substrate 110 through the openings 141, 142 of the passivation layer 140. Therefore, the openings 141, 142 can also be referred to as LCO (Local Contact Opening).

This aspect of the metallic layer 157 of the contact structure 150 is illustrated in FIG. 4. Here, the solar cell 100 can have contact points 158 alloyed in the substrate 110 as required by the manufacturing process, the metallic layer 157 contacts the substrate 110 in region thereof. The contact points 158 can have at least one partially eutectic Aluminum-Silicon alloy. Further there can be local rear side fields (BSF, Back Surface Field) in the region of the contact points 158.

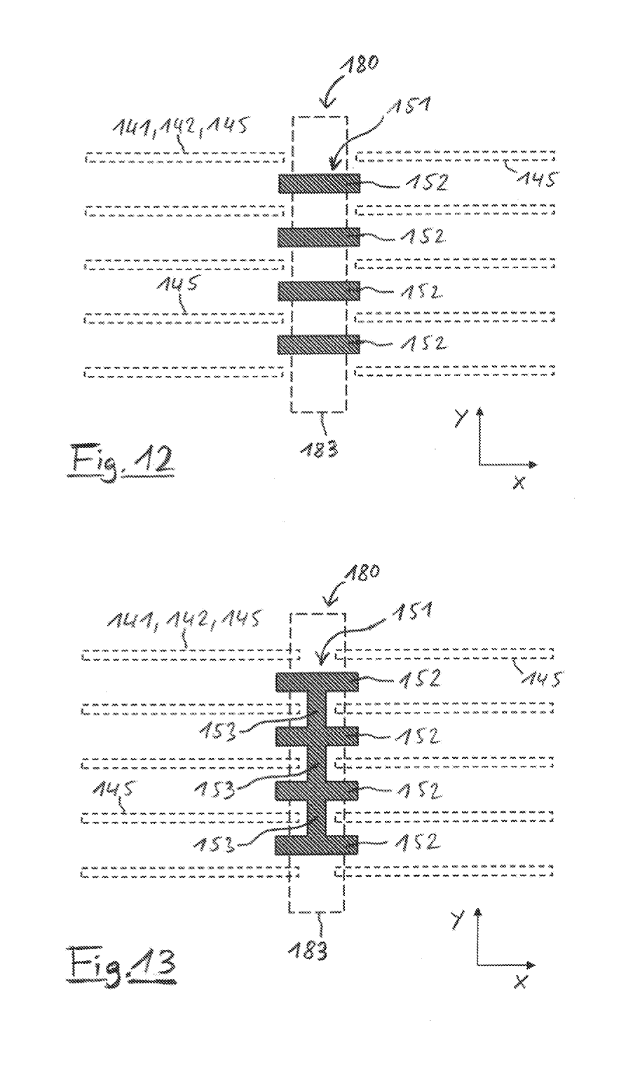

With reference to the connection structures 151 of the rear side contact structure 150 shown in FIG. 2, the solar cell 100 can be configured such that the connection structures 151 are disposed only on the passivation layer 140 and do not directly contact the substrate 110, and the contacting of the substrate 110 takes place only through the metallic layer 157 (c.f. FIGS. 10, 11). This will be discussed in more details further below.

FIG. 3 shows a top view representation of the locally opened passivation layer 140 of the solar cell 100, with the help of which, further details will become clear. The contact openings 141, 142 of the passivation layer 140 are disposed in the engraving of parallel extending and equidistance lines, so that the rear side contact structure 150 or the metallic layer 157 locally contacts the semiconductor substrate 110 in linear contacting regions 145, as indicated in FIG. 3 with the help of dashed lines. In the present case, the contacting regions 145 extend along x-direction, i.e. perpendicular to the rows of connection structures 151 (c.f. FIG. 2) oriented in y-direction. According to the above mentioned abbreviation LCO for the openings 141, 142 of the passivation layer 140, the contacting regions 145 can also be referred to as LCO-Lines.

Different configurations can be considered with reference to the openings 141, 142 of the contacting regions 145. For example, it is possible that openings 141 are configured in the form of linear segments, as it is partially illustrated in FIG. 5 for a contacting region 145. In FIG. 3, one such configuration is indicated with the help of the dashed lines for the contacting regions 145. In another possible and partially represented configuration in FIG. 6 for a contacting region 145, openings 142 are configured in the form of continuous linear structures.

The top view representation of the passivation layer 140 of FIG. 3 shows another feature of the solar cell 100. The passivation layer 140 has respectively one openings-free region 180 extending along the relevant connection element 131, i.e. in the y-direction, in a region under a connection element 131 of the front side contact structure 130. Here, it respectively involves a strip-shaped or rectangular region 180, in which the passivation layer 140 is configured without openings 141, 142. Therefore, linear contacting regions 145 respectively end on both sides at the openings-free regions 180.

The closed configuration of the passivation layer 140 under the connection elements 131 of the front side contact structure 130 takes into account the fact that these regions are subjected to a shadow during the operation of the solar cell 100 in a photovoltaic module. This is due to the connection elements 131 and the cell connector connected to the connection elements 131. In the shaded regions, none or substantially no charge carriers are generated through radiation absorption in the semiconductor substrate 110, and therefore none or substantially no current is generated. The passivation layer 140 adapted thereto at these points has an openings-free region 180, which extends along the corresponding connection element 131. In this way, the shaded regions are not used for contacting the semiconductor substrate 110 and conducting electric current. This configuration enables an efficient passivation of the semiconductor substrate 110 through the passivation layer 140.

For example, the openings-free regions 180 of the passivation layer 140 can have a width in the range of 1 mm or a width in the lower millimetre range in single-digit. For example, a width in the range of 1 mm to 3 mm is possible.

For example, the width of the openings-free regions 180 can be adapted with respect to the width of the front side connection elements 131. For example, the front side connection elements 131 can have a width of 1.4 mm. In this context, an overlapping region 183 can be considered, in which the passivation layer 140 is respectively covered by a front side connection element 131. Here, in the following described configurations for the openings-free regions 180 of the passivation layer 140 of the solar cell 100 can be considered.

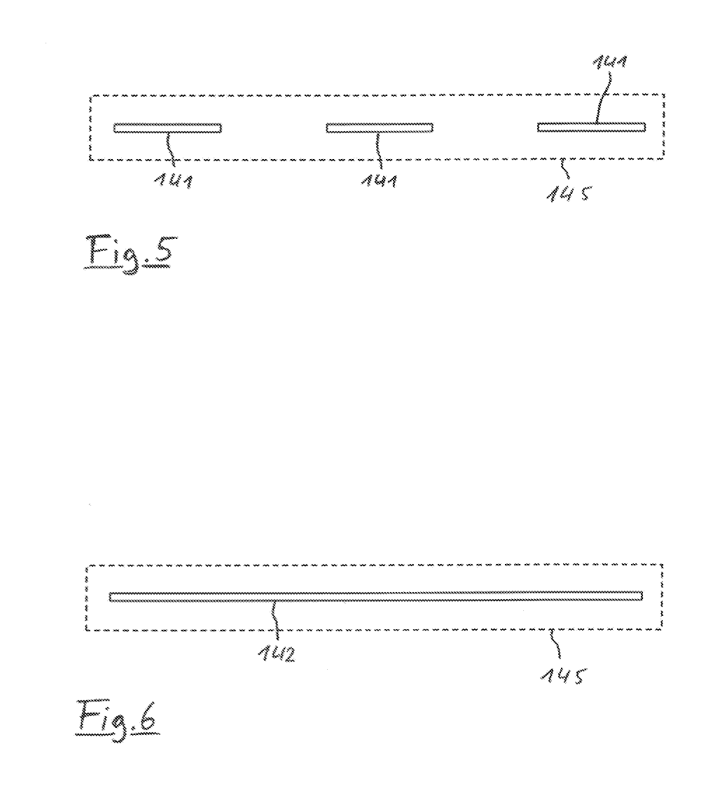

FIG. 7 shows a top view representation in the region of an openings-free region 180. With the help of dashed lines, an overlapping region 183 is indicated, which comes from a front side connection element 181. According to FIG. 7, the openings 141, 142 of the passivation layer 140 present on both sides of the openings-free region 180 and thereby the linear contacting regions 145 are disposed at a distance from the overlapping region 183. Accordingly, the openings-free region 180 has a width 190, which is greater than the width 193 of the overlapping region 183. This configuration encourages a reliable passivation of the semiconductor substrate 110 through the passivation layer 140.

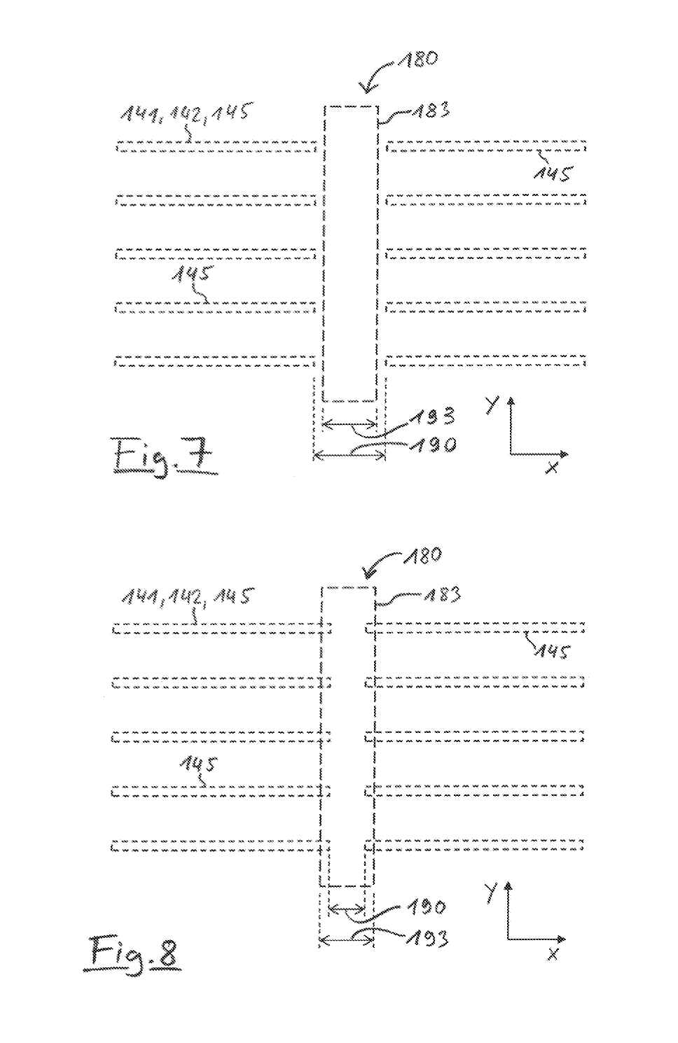

The top view representation in the region of an openings-free region 180 of FIG. 8 shows another possible configuration. Here, the openings 141, 142 of the passivation layer 140 and thereby the contacting regions 145 are partially disposed within a corresponding overlapping region 183 of a connection element 181. Therefore, the width 190 of the openings-free region 180 is smaller than the width 193 of the overlapping region 183. This configuration is based on the possible fact that there is no complete shadow in the overlapping region 183 at least on the border and thereby no charge carriers can be generated at this position. These charge carriers can be dissipated through the contacting regions 145 partially available within the overlapping region 183.

The width of the openings-free region 180 can also be adapted with respect to the width of the cell connector provided for connecting the front side connection elements 131. In the top view representation of FIG. 9, a cell connector 170 connected to a front side connection element 131 is partially indicated for illustration. The cell connector 170, which is realized in the form of a tin-plated copper strip and can be connected to the connection element 131 by soldering, has a larger width than the connection element 131. For example, the width of the cell connector 170 can be 1.7 mm.

FIGS. 7, 8 can be used accordingly in the construction of the openings-free regions 181 with reference to cell connector. In this respect, the represented overlapping region 183 now refers to a cell connector 170 connected to a front side connection element 131 corresponding to FIG. 9. It is possible that the contacting regions 145 are configured spaced from the overlapping region 183 of the cell connector 170 (c.f. FIG. 7) or that the contacting regions 145 are configured partially extending into the overlapping region 183 (c.f. FIG. 8). The first variant in which the width 190 of the openings-free region 180 exceeds the width 193 of the overlapping region 183, encourages a reliable passivation of the semiconductor substrate 110. The second variant, in which the width 190 is smaller than the width 193, takes into account the condition of only a partial shadow on the border of the overlapping region 183.

Possible configurations are described with the help of the following figures, which can be considered for the connection structures 151 of the rear side contact structure 150 represented in FIG. 2. The connection structures 151 are used as the front side connection elements 131 for connecting cell connectors. It is pointed out that corroborative aspects as well as same and similarly working structures and components will not be described again in detail. Instead, a reference is made to the preceding description for details thereof. In addition, aspects and details which are mentioned with reference to one of the following configurations can also be used in other configuration or it is possible to combine features of several configurations.

As mentioned above, the connection structures 151 can be configured segmented. In this sense, FIG. 10 shows a top view representation in the area of an openings-free region 180, wherein linear contacting regions 145 are partially disposed within an overlapping region 183 according to FIG. 8. FIG. 10 shows further a possible configuration, which can be provided for the connection structures 151 of the solar cell 100. The connection structure 151 represented here has a segmented construction with four connection segments 152 separated from each other. The connection segments 152 have a strip-shaped or rectangular contour, and are adjacently disposed in a row in the y-direction.

The connection segments 152 have a length (referring to the x-direction), which exceeds the width of the openings-free region 180 and the width of the overlapping region 183. In addition, the connection segments 152 are located in areas between the contacting regions 145 or between lines of the underlying engraving of the contacting regions 145 not represented. In this way, the connection segments 152 of the connection structure 151 are located exclusively on the passivation layer 140. This construction is also clear from FIG. 11, in which a side sectional view of the rear side of the solar cell 100 is shown in the region of the segmented connection structure 151 of FIG. 10. The section plane refers to the section line indicated in FIG. 10. Details of the front side are omitted in FIG. 11.

Further, overlapping regions 159 between the connection segments 152 and the metallic layer 157 laterally surrounding the connection structure 151 or the connection segments 152 thereof are indicated in FIG. 11. In the overlapping regions 159, the different metallic materials of the connection segments 152 of the connection structure 151 and of the metallic layer 157, i.e. Silver and Aluminum, can be present in intermixed form or at least partially in the form of an alloy.

In such a configuration of the connection structures 151 of the solar cell 100, in which the connection structures 151 are disposed exclusively on the passivation layer 140, the semiconductor substrate 110 is locally contacted only through the metallic layer 157 of the rear side contact structure 150. In this way, the solar cell 100 can have a low-contact resistance on the rear side. The use of segmented connection structures 151 makes it further possible to configure the connection structures 151 with a low Silver content. In this way, a cost-saving can be achieved.

Another advantage is possible in terms of connecting the cell connectors by means of soldering. Here, a device can be employed, which has several peaks or solder pins for pressing a cell connector to a connection structure 151 (not represented). In this context, the connection structures 151 can be configured such that the connection segments 152 and the solder pins are adapted to each other in terms of the position and arrangement, and thereby in a soldering process, the connection segments 152 can be located at corresponding positions under the solder pins. This makes it possible to connect a cell connector to a connection structure 151 reliably and with a high mechanical strength of the solder joint.

The rear side construction of the solar cell 100 shown in the FIGS. 10, 11 and FIGS. 2, 3 can be realized as follows. The semiconductor substrate 110 provided with the passivation layer 140 can be subjected to a Laser process, in which the openings 141, 142 can be introduced in the passivation layer 140 by means of a Laser beam. Subsequently in successive printing processes, an Ag-containing paste for the connection structures 151 and thereafter, an Al-containing paste for the metallic layer 157, can be applied on the rear side of the substrate 110 with the opened passivation layer 140. Here, the printed metallic layer 157 overlaps the printed connection structures 151 or the connection segments 152 thereof on the border. In the above mentioned high temperature process (firing), the pastes can be solidified and the layer 157 can be electrically connected to the substrate 110. Diffusion and intermixing processes occurring during this process lead to forming the contact points 158 and overlapping regions 159.

The top view representation in the region of an openings-free region 180 of FIG. 12 shows another possible configuration, which can be provided for the solar cell 100. Here, the linear contacting regions 145 are disposed spaced from an overlapping region 183 according to FIG. 7. The connection structure 151 shown in FIG. 12 has the above explained construction with separate connection segments 152. Even in this configuration, the connection segments 152 have a length, which exceeds the width of the openings-free region 180 or the width of the overlapping region 183. Further, the connection segments 152 are located in regions between lines of the underlying engraving of the contacting regions 145 not represented, and thereby exclusively on the passivation layer 140.

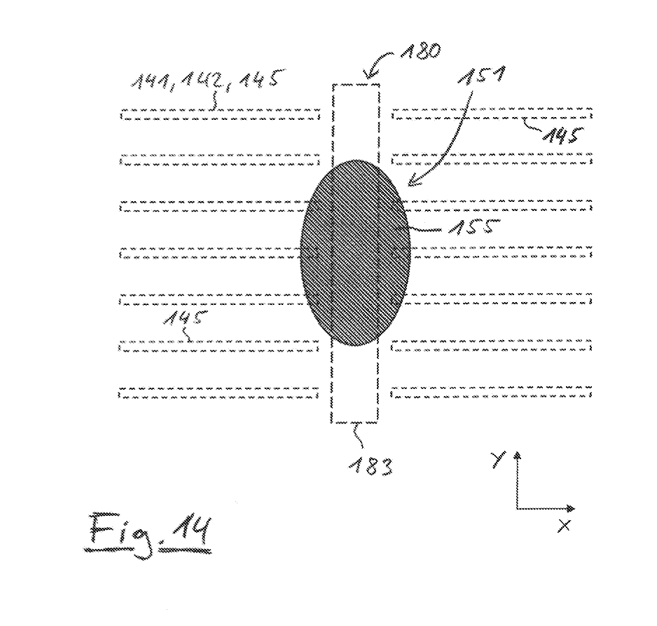

The top view representation in the region of an openings-free region 180 of FIG. 13 shows another possible configuration, which can be considered for the solar cell 100 or the connection structures 151 thereof. Here, the linear contacting regions 145 corresponding to the FIGS. 8, 10 are partially disposed within an overlapping region 183. A configuration corresponding to the FIGS. 7, 12, not represented, is also possible.

The connection structure 151 in addition to that shown in FIG. 13 has again four connection segments 152 disposed in a row in the y-direction. Notwithstanding the configurations shown in the FIGS. 10, 12, the connection segments 152 of the connection structure 151 of FIG. 13 are interconnected via centrally disposed connection bridges 153. The connection bridges 153 are configured from the same material as the connection segments 152, i.e. Silver. Thus, it is possible to connect a cell connector to the connection structure 151 or to the connection bridges 153 present here, also between connection segments 152.

The connection structure 151 of FIG. 13 is likewise exclusively located on the passivation layer 140. This can be realized, as is shown in FIG. 13, in which the connection bridges 153 are configured with smaller width opposite the openings-free region 180 or in which the linear contacting regions 145 end on both sides of the connection bridge 153 at a distance from the connection bridges 153.

The solar cell 100 or the rear side contact structure 150 thereof cannot be realized only with segmented connection structures 151. A configuration with flat structures or connection surfaces is also possible.

For illustrating such a configuration considered for the solar cell 100, FIG. 14 shows another top view representation in the region of an openings-free region 180. Here, the openings 141, 142 of the passivation layer 140 and thereby the linear contacting regions 145 are again disposed spaced from an overlapping region 183 according to FIG. 7. A configuration corresponding to FIG. 8, not represented, is also possible.

In the region shown in FIG. 14, the solar cell 100 has a connection structure 151 in the form of a flat connection elements 155 used for connecting a cell connector. The connection element 155 can have an oval or elliptical form as is represented in FIG. 14. The connection element 155 is likewise configured from a solderable metallic material or Silver and laterally surrounded by the metallic layer 157 of the rear side contact structure 150 (not represented). All the connection structures 151 indicated in FIG. 2 can be configured in the form of such connection surfaces 155 according to FIG. 14.

As shown is in FIG. 14, the linear contacting regions 145 can partially extend under the connection elements 155. In this way, even the connection element 155 can contact the semiconductor substrate 110 of the solar cell 100. Alternatively, the connection element 155 and/or the contacting regions 145 can be configured such that there is no such contacting and the connection element 155 is disposed only on the passivation layer 140 (not represented).

The embodiments explained with the help of the figures represent preferred or exemplary embodiments of the invention. Besides the described and depicted embodiments, further embodiments can be conceived, which can include further variations and/or combinations of features.

For example, it is instead possible to use other than above specified materials. Same applies for the numerical data, for example for the number of connection elements 131, connection structures 151 and connection segments 152 of segmented connection structures 151 shown in the figures, which can be replaced by other data.

In addition, segmented connection structures 151 with geometric forms differing from the top view forms of the figures can be realized. For example, it is also possible to provide connection segments with partially curved contours instead of exclusively rectangular connection segments 152. Further, mixed configurations of segmented connection structures 151 can be conceived, which have connected as well as separated connection segments 152.

Other geometric top views can also be considered for connection structures 151 in the form of flat connection elements 155. For example, connection elements 155 with a rectangular shape are considered thereunder.

With regard to overlapping regions 183, configurations are possible, in which openings 141, 142 of the passivation layer 140 or linear contacting regions 145 are respectively configured reaching an overlapping region 183. Here, the overlapping region 183 and the corresponding openings-free region 180 can respectively be mutually congruent and have matching dimensions or widths.

### LIST OF REFERENCE NUMERALS

100 Solar cell

110 Substrate

111 Base

112 Emitter

115 Front side

116 Rear side

120 Antireflective coating

130 Contact structure

131 Connection element

135 Contact finger

140 Passivation layer

141 Opening

142 Opening

145 Contacting region

150 Contact structure

151 Connection structure

152 Connection segment

153 Connection bridge

155 Connection element

157 Metallic layer

158 Contact point

159 Overlapping region

170 Cell connector

180 Openings-free region

183 Overlapping region

190 Width

193 Width

x, y Direction

1. Solar cell comprising a semiconductor substrate with a first and second side, a first contact structure disposed in the region of the first side of the semiconductor substrate and contacting the semiconductor substrate, a passivation layer with openings disposed on the second side of the semiconductor substrate, and a second contact structure disposed on the passivation layer, which locally contacts the semiconductor substrate through the openings of the passivation layer,
wherein the first contact structure has a strip-shaped connection element and contact fingers connected to the connection element,
and wherein the passivation layer has an openings-free region extending along the connection element in a region under the strip-shaped connection element of the first contact structure.

2. Solar cell according to claim 1, wherein the openings of the passivation layer are disposed in an engraving of lines extending in parallel, so that the second contact structure locally contacts the semiconductor substrate in linear contacting region.

3. Solar cell according to claim 1, wherein the passivation layer is covered by the strip-shaped connection element of the first contact structure in an overlapping region,
and wherein the openings of the passivation layer are disposed spaced from the overlapping region of the connection element.

4. Solar cell according to claim 1, wherein the passivation layer is covered by the strip-shaped connection element of the first contact structure in an overlapping region,
and wherein the openings of the passivation layer are disposed partially within the overlapping region of the connection element.

5. Solar cell according to claim 2, wherein the second contact structure comprises a connection structure with several connection elements and a metallic layer surrounding the connection elements of the connection structure,
wherein the connection structure has a first metallic material, which is solderable,
wherein the metallic layer has a second metallic material,
and wherein the metallic layer locally contacts the semiconductor substrate only through the openings of the passivation layer.

6. Solar cell according to claim 5, wherein the connection structure comprises connection elements separated from each other.

7. Solar cell according to claim 5, wherein the connection structure comprises connection elements connected to each other.

8. Arrangement comprising a solar cell according to claim 1 and a cell connector connected to the strip-shaped connection element of the first contact structure.

9. Arrangement according to claim 8, wherein the passivation layer is covered by the cell connector in an overlapping region,
and wherein the openings of the passivation layer are disposed spaced from the overlapping region of the cell connector.

10. Arrangement according to claim 8, wherein the passivation layer is covered by the cell connector in an overlapping region,
and wherein the openings of the passivation layer are disposed partially within the overlapping region of the cell connector.
